(19) United States
(12) Patent Application Publication
(10) Pub. No.: US 2019/0363302 A1
(43) Pub. Date: Nov. 28, 2019

(54) SUBSTRATE MOUNTING STAGE, INK-JET APPLYING DEVICE, LEVELING DEVICE, AND METHOD FOR MANUFACTURING ORGANIC EL DISPLAY DEVICE

(71) Applicant: SHARP KABUSHIKI KAISHA, Sakai City, Osaka (JP)

(72) Inventors: Jumpei TAKAHASHI, Sakai City (JP); Takeshi HIRASE, Sakai City (JP); Hisao OCHI, Sakai City (JP); Takashi OCHI, Sakai City (JP); Tohru SENOO, Sakai City (JP); Tohru SONODA, Sakai City (JP); Akihiro MATSUI, Sakai City (JP); Yoshinobu MIYAMOTO, Sakai City (JP)

(73) Assignee: Sharp Kabushiki Kaisha, Sakai City, Osaka (JP)

(21) Appl. No.: 16/064,468

(22) PCT Filed: Feb. 27, 2017
(86) PCT No.: PCT/JP2017/007401

§ 371 Date: Aug. 30, 2018

(51) Int. Cl. H01L 51/56; H01L 51/00; H01L 27/32

(52) U.S. Cl. CPC H01L 51/56; H01L 51/0026; H01L 27/3246; H01L 51/0005

(57) ABSTRACT

A substrate mounting portion includes a low temperature portion whose temperature is adjusted to an atmospheric temperature or lower at a position corresponding to a frame-shaped bank surrounding a pixel formation region of a substrate. An edge width of a sealing layer is narrowed with this configuration.

### TECHNICAL FIELD

The disclosure relates to a substrate mounting stage, an ink-jet applying device, a leveling device, and a method for manufacturing an organic EL display device.

### BACKGROUND ART

PTL 1 discloses a configuration in which a substrate mounting stage is provided with a mechanism for heating a mounted substrate.

### CITATION LIST

### Patent Literature

PTL 1: JP 2010-131491 A

### SUMMARY

### Technical Problem

In an organic EL display device, in order to seal an organic EL layer of a pixel, a sealing layer is formed on the entire surface of a pixel formation region. In the sealing layer, after forming a frame-shaped bank surrounding the pixel formation region in a frame shape, an ink material is applied in the frame-shaped bank by an ink-jet method, and the ink material is cured. At this time, in order to form a flat sealing layer, the applied ink material is leveled (subjected to leveling) before being cured. However, when this ink material is subjected to leveling, in a case where a temperature in the vicinity of the frame-shaped bank is high, the ink tends to spread out over the frame-shaped bank, a width of an edge portion of the sealing layer with a nonuniform film thickness widens, and thus frame narrowing cannot be achieved.

The disclosure has been made in view of the above-described known problems, and an object thereof is to narrow an edge width of a sealing layer.

### Solution to Problem

In order to solve the above-described problems, a substrate mounting stage according to one aspect of the disclosure is a substrate mounting stage mounted with organic EL display panel formation regions disposed in a matrix shape, a pixel formation region with pixels disposed in a matrix shape, a frame-shaped bank surrounding the pixel formation region in a frame shape, and an ink material before being cured applied by an ink-jet method configured to cover the pixel formation region in the frame-shaped bank being disposed in the organic EL display panel formation region, the substrate mounting stage includes temperature adjustment portions subjected to a temperature adjustment and disposed in a matrix shape, in which the temperature adjustment portion includes a low temperature portion disposed at a position corresponding to the frame-shaped bank in a frame shape and having a first temperature being an atmospheric temperature or lower.

In order to solve the above-described problems, a method for manufacturing an organic EL display device according to one aspect of the disclosure is a method for manufacturing an organic EL display device to manufacture an organic EL display device from a substrate with organic EL display panel formation regions disposed in a matrix shape, a pixel formation region with pixels disposed in a matrix shape, a frame-shaped bank surrounding the pixel formation region in a frame shape, and an ink material before being cured applied by an ink-jet method configured to cover the pixel formation region in the frame-shaped bank being disposed in the organic EL display panel formation region, the method includes temperature-adjusting a temperature of a position corresponding to the frame-shaped bank of the substrate to a first temperature being an atmospheric temperature or lower after the ink material is applied by the ink-jet method.

### Advantageous Effects of Disclosure

According to one aspect of the disclosure, an effect that an edge width of a sealing layer can be narrowed is achieved.

### BRIEF DESCRIPTION OF DRAWINGS

FIG. 1 is a diagram illustrating steps of manufacturing an organic EL display device according to a first embodiment of the disclosure.

FIG. 2 is a plan view of a substrate of the organic EL display device according to the first embodiment of the disclosure.

FIG. 3 is a cross-sectional view in a vicinity of an organic EL display panel formation region of the substrate in FIG. 2.

FIG. 4 is a diagram illustrating an overview of a sealing system forming a sealing layer of the organic EL display device according to the first embodiment of the disclosure.

FIG. 5 is a diagram illustrating an overall configuration of an ink-jet applying device of the sealing system.

FIG. 6 is a diagram illustrating an overall configuration of a leveling device of the sealing system.

FIG. 7 is a graph illustrating a relationship between an edge width of the sealing layer of the organic EL display device and leveling time.

FIG. 8 is a plan view illustrating a configuration of a substrate mounting portion included in a device in the sealing system.

FIG. 9 is a cross-sectional view in the vicinity of the organic EL display panel formation region of a substrate mounted on the substrate mounting portion before an ink material is cured.

FIG. 10 is a cross-sectional view in the vicinity of the organic EL display panel formation region of the substrate mounted on the substrate mounting portion according to the first embodiment of the disclosure after the ink material is cured.

FIG. 11 is a plan view illustrating a configuration of the substrate mounting portion according to a second embodiment of the disclosure.

FIG. 12 is a cross-sectional view in the vicinity of the organic EL display panel formation region of the substrate mounted on the substrate mounting portion.

FIG. 13 is a diagram illustrating an overall configuration of a water cooling type heat insulating portion.

FIG. 14 is a cross-sectional view in the vicinity of the organic EL display panel formation region of the substrate mounted on the substrate mounting portion according to the second embodiment of the disclosure after the ink material is cured.

FIG. 15 is a plan view illustrating a configuration of the substrate mounting portion according to a third embodiment of the disclosure.

FIG. 16 is a cross-sectional view in the vicinity of the organic EL display panel formation region of the substrate mounted on the substrate mounting portion.

FIG. 17 is a cross-sectional view in the vicinity of the organic EL display panel formation region of the substrate mounted on the substrate mounting portion according to the third embodiment of the disclosure after the ink material is cured.

FIG. 18 is a diagram illustrating an overall configuration of a water cooling type low temperature portion.

FIGS. 19A to 19C are diagrams illustrating the substrate mounting portion and a set temperature according to a fourth embodiment of the disclosure.

### DESCRIPTION OF EMBODIMENTS

### First Embodiment

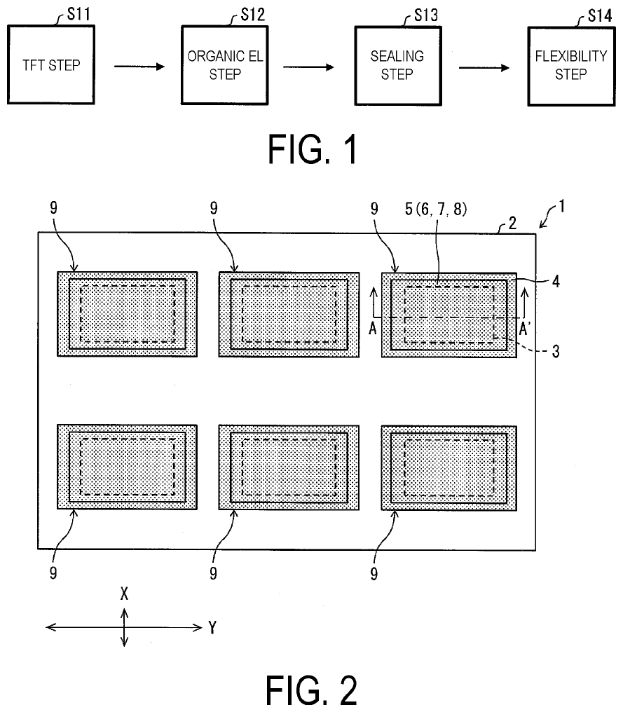

A first embodiment of the disclosure will be described with reference to FIG. 1 to FIG. 9.

### Overview of Method for Manufacturing Organic EL Display Device

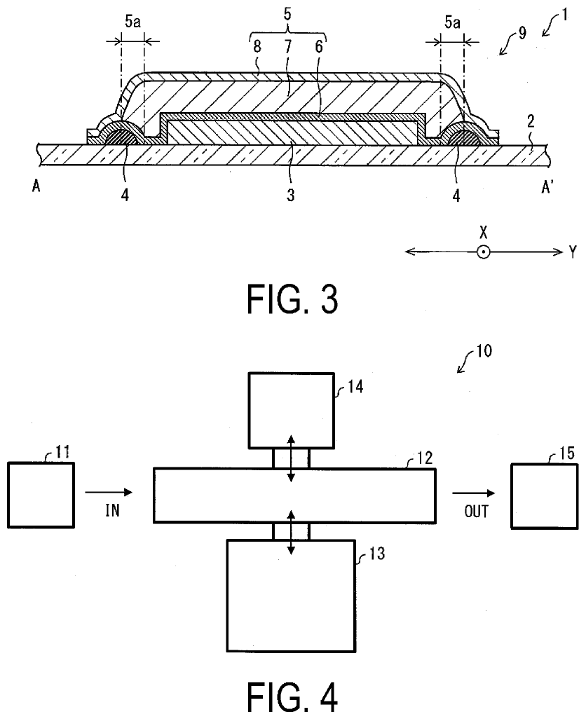

FIG. 1 is a diagram illustrating steps of manufacturing an organic EL display device according to the first embodiment of the disclosure. FIG. 2 is a plan view of a substrate 1 of the organic EL display device according to the first embodiment of the disclosure. FIG. 3 is a cross-sectional view of an organic EL display panel formation region of the substrate in FIG. 2. FIG. 2 illustrates a configuration of a case where six organic EL display panels are obtained from one sheet of a mother glass. Note that, the number of the organic EL display panels obtained from one sheet of the mother glass is not limited to six, and five or less, or seven or more panels may be obtained.

On the substrate 1, six organic EL display panel formation regions 9 are disposed. The organic EL display panel formation region 9 is a region to be the organic EL display device after singulation by being cut out from the mother glass.

The substrate 1 includes a TFT substrate 2, a pixel formation region 3, a frame-shaped bank 4, and a sealing layer 5.

First, in TFT step S11, the TFT substrate 2 is prepared. The TFT substrate 2 is prepared by a thin film transistor (transistor, drive element) for pixel drive, a gate wiring and a source wiring, and other various wirings being formed, and a passivation film (protection film), an interlayer insulating film (flattening film), and the like being formed on the mother glass by a known method.

The passivation film prevents a metal film in the TFT from peeling, and protects the TFT. The passivation film is formed on the mother glass or via other layers, and covers the TFT. The passivation film is an inorganic insulation film formed from silicon nitride, silicon oxide, or the like.

The interlayer insulating film levels concaves and convexes on the passivation film. The interlayer insulating film is formed on the passivation film. The interlayer insulating film is an organic insulating film formed from a photosensitive resin such as acrylic and polyimide.

Next, in organic EL step S12, a reflective electrode and an organic EL layer are formed in each pixel of the TFT substrate 2. Then, a transparent electrode opposing the reflective electrode via the organic EL layer is formed so as to cover the organic EL layer. With this, the pixel formation region 3 in which the pixels are disposed in a matrix shape in a region where an image is displayed is formed. Additionally, when forming this pixel formation region 3, the frame-shaped bank 4 surrounding the pixel formation region 3 in a frame shape is also formed on the TFT substrate 2. The frame-shaped bank 4 is formed from a photosensitive resin such as acrylic and polyimide. The frame-shaped bank 4 can be formed with a thick film thickness of, for example, 1.0 μm or greater, by being formed of acrylic. Furthermore, the frame-shaped bank 4 may be covered by an inorganic film such as a nitride film.

Subsequently, in sealing step S13, the sealing layer 5 is formed. The sealing layer 5 can have a three-layer structure, as an example, in which an inorganic film, an organic film, and an inorganic film are layered in this order.

FIG. 4 is a diagram illustrating an overview of a sealing system 10 for forming the sealing layer 5. The sealing system 10 is an example of a device group for forming the sealing layer 5.

The sealing system 10 includes a first CVD device 11, a substrate transport robot 12, an ink-jet applying device 13, a leveling device 14, and a second CVD device 15.

First, an inorganic film 6 formed from silicon nitride, silicon oxide, or the like is film-formed on the substrate 1 transported from organic EL step S12, by the first CVD device 11, in a region surrounded by the frame-shaped bank 4 including at least the upper portion of the frame-shaped bank 4. The substrate on which the inorganic film 6 is film-formed is, next, carried into the ink-jet applying device 13 through the substrate transport robot 12.

Then, by the ink-jet applying device 13, in a region on the inorganic film 6 and surrounded by the frame-shaped bank 4, an ink material including a photosensitive material such as an acrylic resin, an epoxy resin, polyimide, or the like is applied. The frame-shaped bank 4 functions as a bank for blocking this ink material. Next, the substrate on which the ink material is applied is carried into the leveling device 14 through the substrate transport robot 12.

Then, in the leveling device 14, the substrate on which the ink material is applied is left to stand on a substrate mounting stage for a predetermined period of time. With this, the ink material on the substrate flows and is leveled. Subsequently, after the predetermined period of time has passed, the ink material on the substrate is irradiated with UV light from a UV light source disposed in the leveling device 14. With this, the ink material is cured and an organic film 7 is film-formed on the inorganic film 6.

Next, the substrate on which the organic film 7 is film-formed is carried into the second CVD device 15 through the substrate transport robot 12. Then, by the second CVD device 15, an inorganic film 8 formed from silicon nitride, silicon oxide, or the like is film-formed so as to cover the organic film 7 and the inorganic film 6. With this, as illustrated in FIG. 3, the flat sealing layer 5 is formed.

The organic EL layer formed in the pixel formation region 3 is subjected to Thin Film Encapsulation (TFE) by the sealing layer 5, which prevents the organic EL layer from deteriorating by moisture or oxygen entering from the outside.

After this sealing layer 5 is formed, flexibility step S14 may be provided. In flexibility step S14, glass of the substrate is peeled and a film or the like to be a support body is bonded.

Subsequently, each of the organic EL display panel formation regions 9 is singulated by being cut out. With these steps, the organic EL display device is completed.

### Ink-Jet Applying Device 13

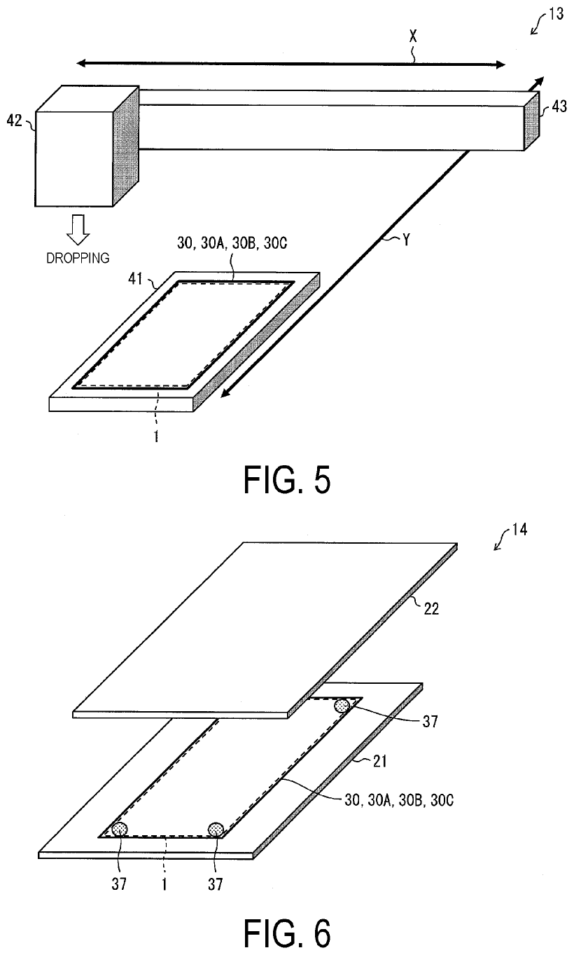

FIG. 5 is a diagram illustrating an overall configuration of the ink-jet applying device 13. The ink-jet applying device 13 includes a substrate mounting stage 41 on which the substrate 1 is mounted, an ink-jet head 42 for dropping the ink material to be the organic film 7, and a head support portion 43 which movably supports the ink-jet head 42.

The substrate mounting stage 41 moves in a Y-axis direction. The ink-jet head 42 moves in an X-axis direction orthogonal to the Y-axis direction.

When the substrate 1 is placed on the substrate mounting stage 41, the substrate mounting stage 41 moves relatively to the ink-jet head 42. In the present embodiment, the substrate mounting stage 41 moves in the Y-axis direction. In other words, the Y-axis direction is an application direction of the ink material to the substrate 1.

Then, the ink material is applied to the substrate 1 mounted on the substrate mounting stage 41 from the ink-jet head 42.

In accordance with a width of the ink-jet head 42 and a width of the substrate 1, as necessary, by the ink-jet head 42 moving in the X-axis direction by a predetermined distance, and the substrate mounting stage 41 moving again in the Y-axis direction, the ink material is applied on a predetermined region on the substrate 1 as a whole.

When the application of the ink material is completed, the substrate 1 on the substrate mounting stage 41 may be taken out from the ink-jet applying device 13 after leveling the ink material by leaving it to stand for a predetermined period of time, or may be taken out from the ink-jet applying device 13 immediately after the application of the ink material is completed.

The substrate mounting stage 41 preferably includes a substrate mounting portion 30, which will be described later, in a region in which the substrate 1 is mounted. Alternatively, the substrate mounting stage 41 may include any one of substrate mounting portions 30A to 30C, which will be described in second to fourth embodiments, instead of the substrate mounting portion 30.

### Leveling Device 14

FIG. 6 is a diagram illustrating an overall configuration of the leveling device 14. In the present embodiment, it is assumed that the leveling device 14 also functions as an ink curing device for curing the ink material applied by an ink-jet method.

The leveling device 14 includes a substrate mounting stage 21 and a UV light source 22. Note that, when an ink curing device is separately provided other than the leveling device 14, the leveling device 14 may not include the UV light source 22.

When the substrate 1 on which the ink material is applied by the ink-jet applying device 13 is transported from the substrate transport robot 12, the substrate 1 is mounted on the substrate mounting stage 21. Then, the substrate 1 is left to stand for a predetermined period of time, for example, three minutes or the like. With this, the ink material applied on the substrate 1 flows and is leveled.

When the predetermined period of time has passed, the UV light source 22 is lighted, and the ink material of the substrate 1 is irradiated with the UV light. With this, the ink material of the substrate 1 is cured and the organic film 7 is film-formed. Note that, when the substrate 1 is irradiated with the UV light, an unevenness reduction measure such as irradiating the substrate 1 being floated by air with the UV light is preferably carried out. After the ink material is cured to film-form the organic film 7, the substrate 1 is taken out from the leveling device 14, and carried into the second CVD device 15, which is a post-step, through the substrate transport robot 12.

The substrate mounting stage 21 preferably includes the substrate mounting portion 30, which will be described later, in the region in which the substrate 1 is mounted. Alternatively, the substrate mounting stage 21 may include any one of the substrate mounting portions 30A to 30C, which will be described in the second to fourth embodiments, instead of the substrate mounting portion 30.

### Film Thickness Unevenness of Edge of Sealing Layer

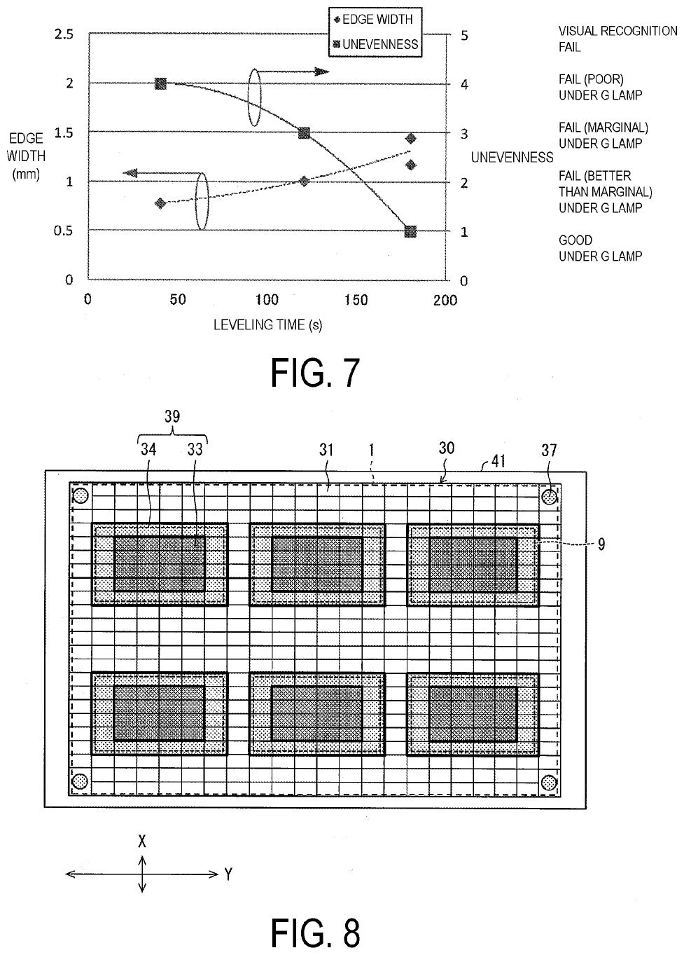

Using FIG. 7, problems to be solved by the substrate mounting portion 30 according to the present embodiment will specifically be described.

FIG. 7 is a graph illustrating a relationship among an edge width of the sealing layer of the organic EL display device manufactured by the known manufacturing method, unevenness of a display unit, and leveling time. The organic EL display device manufactured by the known manufacturing method is an organic EL display device in which the sealing layer is formed by an ink-jet applying device and a leveling device which do not include the substrate mounting portion 30.

The edge width illustrated in FIG. 7 is the edge width of the sealing layer. As illustrated in FIG. 7, when the leveling time of the ink material increases, the ink in the display unit is leveled, and display unevenness due to the nonuniform ink film thickness is difficult to be visually recognized. However, a gentle shape of an edge portion by leveling enlarges an edge width. Note that, the unevenness illustrated in FIG. 7 represents a result obtained by the substrate being irradiated with a Green lamp and visually recognized.

On the other hand, when the leveling time of the ink material is shortened, the ink in the display unit is not sufficiently leveled, and the display unevenness due to the nonuniform ink film thickness is easy to be visually recognized. However, since a steep shape is maintained in the edge portion, the edge width decreases.

Accordingly, as will be described later, forming the sealing layer by the ink-jet applying device 13 or the leveling device 14 including the substrate mounting portion 30 makes it possible to reduce the display unevenness, while reducing the leveling time, and thus, can reduce the edge width.

### Configuration of Substrate Mounting Portion 30

Next, using FIG. 8 to FIG. 10, the configuration of the substrate mounting portion 30 included in at least one of the ink-jet applying device 13 and the leveling device 14 will be described.

The substrate mounting portion 30 may be provided on both the substrate mounting stage 41 of the ink-jet applying device 13 and the substrate mounting stage 21 of the leveling device 14, or may be provided on one of them. The substrate mounting portion 30 may be provided on at least one of the substrate mounting stages 21 and 41. Providing the substrate mounting portion 30 on both the substrate mounting stages 21 and 41 makes it possible to obtain effect of shortening the takt time in comparison with a case of providing on only one of them. Note that, the same applies to the substrate mounting portions 30, 30A to 30C described in the second to fourth embodiments.

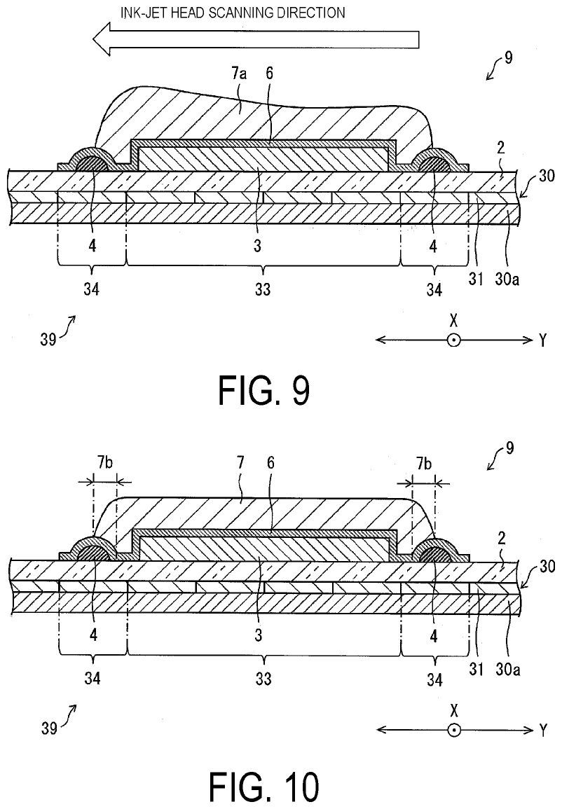

FIG. 8 is a plan view illustrating the configuration of the substrate mounting portion 30. FIG. 9 is a cross-sectional view in the vicinity of the organic EL display panel formation region 9 of the substrate 1 mounted on the substrate mounting portion 30 before an ink material 7a is cured. FIG. 10 is a cross-sectional view in the vicinity of the organic EL display panel formation region 9 of the substrate 1 mounted on the substrate mounting portion 30 after the ink material 7a is cured.

Note that, FIG. 8 illustrates an example in which the substrate mounting portion 30 is provided on the substrate mounting stage 41. Additionally, in FIG. 9, a direction indicated by an arrow (a direction from right toward left in the diagram) is a scanning direction of an ink-jet head (an application direction of the ink material 7a).

As illustrated in FIG. 8, in the substrate mounting portion 30, temperature adjustment portions 39 are disposed in a matrix shape while being separated from each other.

The substrate mounting portion 30 inquires of a lookup table, before the substrate 1 being mounted, on information of the substrate 1 (a model number of the panel, a position of the frame-shaped bank, a position of the pixel formation region, the application direction, or the like) and adjusts temperature of the temperature adjustment portions 39 on the basis of the information of the substrate 1.

On four corners of the substrate mounting portion 30, lift pins 37 for lifting up the substrate 1 when transporting the substrate 1 are disposed. In the substrate mounting portion 30, temperature adjustment elements 31 are disposed in a matrix shape on a stage base material 30a formed from a metal material. In the present embodiment, the temperature adjustment elements 31 are disposed on the entire surface of the substrate mounting portion 30 which is a region in which the substrate 1 is placed such that the adjacent temperature adjustment elements 31 in the X direction and the Y direction make contact with each other. The temperature of each of the temperature adjustment elements 31 can be individually adjusted.

The temperature adjustment element 31 may be set to have various sizes in accordance with the size of the substrate 1. As one example, the temperature adjustment element 31 can be made to have a size of approximately 1 mm square. The temperature adjustment element 31 may be a heat source capable of being adjusted so as to have two different temperatures and maintaining the temperatures. In the present embodiment, it is assumed that the temperature adjustment element 31 is a Peltier element.

As illustrated in FIG. 8 and FIG. 9, in the substrate mounting portion 30, the temperature adjustment elements 31 whose temperatures are adjusted at a position at which the organic EL display panel formation region 9 of the substrate 1 is disposed are the temperature adjustment portion 39. In the temperature adjustment portion 39, a region in which the pixel formation region 3 of the substrate 1 is disposed configures a high temperature portion 33 whose temperature is higher than an atmospheric temperature, and a region in which the frame-shaped bank 4 is disposed configures a low temperature portion 34 whose temperature is lower than the atmospheric temperature.

In other words, the substrate mounting portion 30 forms the temperature adjustment portion 39 so as to overlap with the organic EL display panel formation region 9.

Note that, the atmospheric temperature refers to a peripheral temperature of the substrate mounting portion 30. In other words, the atmospheric temperature is the peripheral temperature of the substrate mounting stage 21 or the substrate mounting stage 41 in which the substrate mounting portion 30 is included. The atmospheric temperature is a temperature of approximately from no lower than 20° C. to no higher than 25° C., for example.

The high temperature portion 33 is configured of the plurality of temperature adjustment elements 31. In the high temperature portion 33, the temperature of the temperature adjustment element 31 is, as an example, approximately from no lower than 30° C. to no higher than 60° C.

The low temperature portion 34 is configured of the plurality of temperature adjustment elements 31. In the low temperature portion 34, the temperature of the temperature adjustment element 31 is, as an example, approximately from no lower than 10° C. to no higher than 25° C. Note that, the highest temperature of the low temperature portion 34 may be the atmospheric temperature.

The organic EL display panel formation regions 9 are disposed in a matrix shape on the substrate 1 mounted on the substrate mounting portion 30. In the organic EL display panel formation region 9, the pixel formation region 3 in which pixels are disposed in a matrix shape, the frame-shaped bank 4 surrounding the pixel formation region 3 in a frame shape, and the ink material 7a applied by the ink-jet applying device 13 so as to cover the pixel formation region 3 in the frame-shaped bank 4 are disposed.

The substrate mounting portion 30 includes the temperature adjustment portions 39 disposed in a matrix shape, each temperature of which being adjusted. The temperature adjustment portion 39 includes the low temperature portion 34 and the high temperature portion 33, each temperature of which being adjusted.

The low temperature portion 34 is disposed in a frame shape at a position corresponding to the frame-shaped bank 4, and has a first temperature which is the atmospheric temperature or lower. In other words, the low temperature portion 34 is disposed at a position overlapping with the frame-shaped bank 4.

Accordingly, after the ink material 7a is dropped from a nozzle of the ink-jet head 42 and applied on the substrate 1, it is possible to suppress the ink material 7a from flowing in the vicinity of the frame-shaped bank 4. With this, it is possible to suppress the ink from flowing over the frame-shaped bank 4, and as illustrated in FIG. 10, a width of an edge portion 7b, which is a portion having a different film thickness in an organic film 7 formed by the cured ink material 7a, can be narrowed.

As illustrated in FIG. 3, forming an inorganic film 8 on the organic film 7 makes it possible to form the sealing layer 5 in which a width of an edge portion 5a, which is a portion having a different film thickness, is narrow.

Accordingly, a high quality sealing layer 5 can be formed by the ink-jet method. Additionally, the organic EL display device having a frame region with a narrow width in the periphery of the pixel formation region 3 can be formed.

Furthermore, as illustrated in FIG. 8 and FIG. 9, the high temperature portion 33 is disposed at a position in a region surrounded by the low temperature portion 34 and corresponding to the pixel formation region 3. In other words, the high temperature portion 33 is disposed at a position overlapping with the pixel formation region 3. Additionally, the high temperature portion 33 has a second temperature higher than the atmospheric temperature. In other words, the high temperature portion 33 is adjusted to have a higher temperature than the low temperature portion 34.

Accordingly, heating a portion covering the pixel formation region 3 in the ink material 7a applied on the substrate 1 promotes flowing and promotes leveling of the ink material 7a. With this, time in relation to a leveling process of the ink material 7a can be shortened. In other words, the leveling time of the ink material 7a can be shortened.

As a result, as illustrated in FIG. 10, a flat organic film 7 can be formed in a short period of time.

Then, as illustrated in FIG. 3, forming the inorganic film 8 on the organic film 7 makes it possible to form the flat sealing layer 5.

Furthermore, as illustrated in FIG. 8 and FIG. 9, in the substrate mounting portion 30, the temperature adjustment elements 31 capable of being set to the first temperature and the second temperature are disposed in a matrix shape. In the present embodiment, particularly, in the substrate mounting portion 30, the temperature adjustment elements 31 are disposed on almost the entire surface of the region excluding the region in which the lift pins 37 are disposed. As an example of the temperature adjustment element 31, the Peltier element can be used.

As the temperature adjustment element 31 configuring the high temperature portion 33, various heating mechanisms such as a heating mechanism for heating by flowing a current through a resistor, or the like can be used other than the Peltier element. However, as the temperature adjustment element 31, the Peltier element is preferably used. This is because both the temperature adjustment element 31 configuring the high temperature portion 33 and the temperature adjustment element 31 configuring the low temperature portion 34 can be configured of the Peltier element and a high efficiency is obtained.

Additionally, the low temperature portion 34 and the high temperature portion 33 are each configured of the plurality of temperature adjustment elements 31.

With this, in accordance with shapes of the frame-shaped bank 4 and the pixel formation region 3, the temperature adjustment elements 31 on a required portion are set to the first temperature or the second temperature, thus, the low temperature portion 34 and the high temperature portion 33 can be provided. Accordingly, the substrate mounting portion 30 with high versatility can be obtained.

Note that, in the present embodiment, although the description has been given assuming that the substrate mounting portion 30 includes the low temperature portion 34 and the high temperature portion 33, the configuration may be such that the high temperature portion 33 is not included and only the low temperature portion 34 is included.

Additionally, the lift pins 37 may be disposed, in the substrate mounting portion 30, not only on the four corners of the substrate 1, but also on positions overlapping with the region where the ink material 7a is applied in some cases. Accordingly, when the substrate mounting portion 30 is provided on the substrate mounting stage 21 and when the leveling device also functions as the ink curing device, it is preferable to make reflectivity in the ink material applying region uniform such that reflectivity of the UV light will not change despite the positions of the lift pins 37, by plating in the same manner as the stage portion surface, applying a polyimide (PI) material having substantially the same UV reflectivity as the surface of the substrate mounting portion 30, or the like on the surface of the lift pin 37.

### Second Embodiment

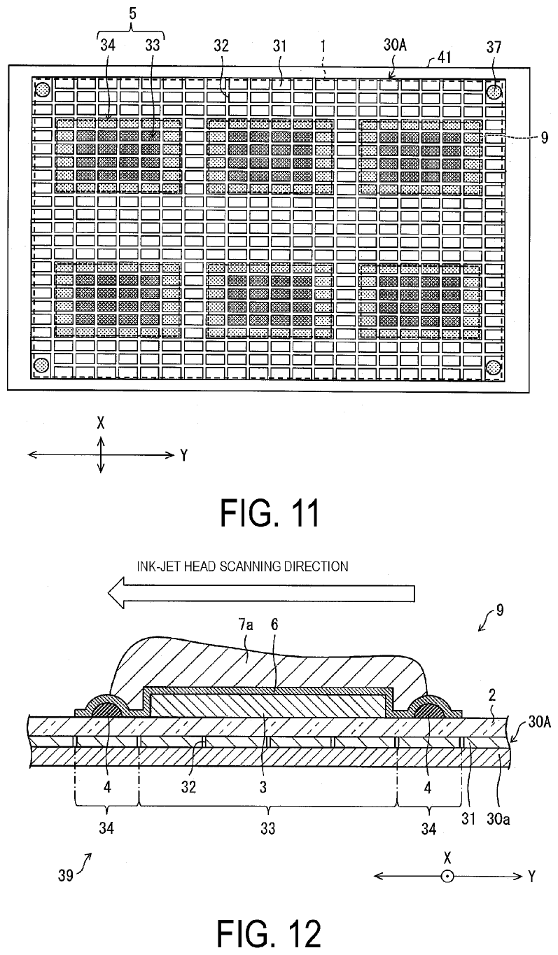

A second embodiment of the disclosure will be described with reference to FIG. 11 to FIG. 14. FIG. 11 is a plan view illustrating a configuration of the substrate mounting portion 30A according to the second embodiment of the disclosure. FIG. 12 is a cross-sectional view in the vicinity of the organic EL display panel formation region of the substrate 1 mounted on the substrate mounting portion 30A. FIG. 14 is a cross-sectional view in the vicinity of the organic EL display panel formation region 9 of the substrate 1 mounted on the substrate mounting portion 30A after the ink material 7a is cured. Note that, in FIG. 12, a direction indicated by an arrow (a direction from right toward left in the diagram) is the scanning direction of the ink-jet head (the application direction of the ink material 7a).

The substrate mounting portion 30A may be provided on at least one of the substrate mounting stage 41 of the ink-jet applying device 13 (FIG. 5) and the substrate mounting stage 21 of the leveling device 14 (FIG. 6).

As illustrated in FIG. 11 and FIG. 12, the substrate mounting portion 30A is configured such that a heat insulating portion 32 is disposed between the temperature adjustment elements 31 disposed in a matrix shape in the substrate mounting portion 30. The other configurations of the substrate mounting portion 30A are the same as those of the substrate mounting portion 30.

The heat insulating portion 32 is provided in the periphery of the temperature adjustment element 31 in a grid shape. The heat insulating portion 32 can be configured of air, water, and other heat insulating materials. In a case where the heat insulating portion 32 is configured of air, it is sufficient for the heat insulating portion 32 to be a groove recessed from a surface of the substrate mounting portion 30A (a mounting surface of the substrate 1).

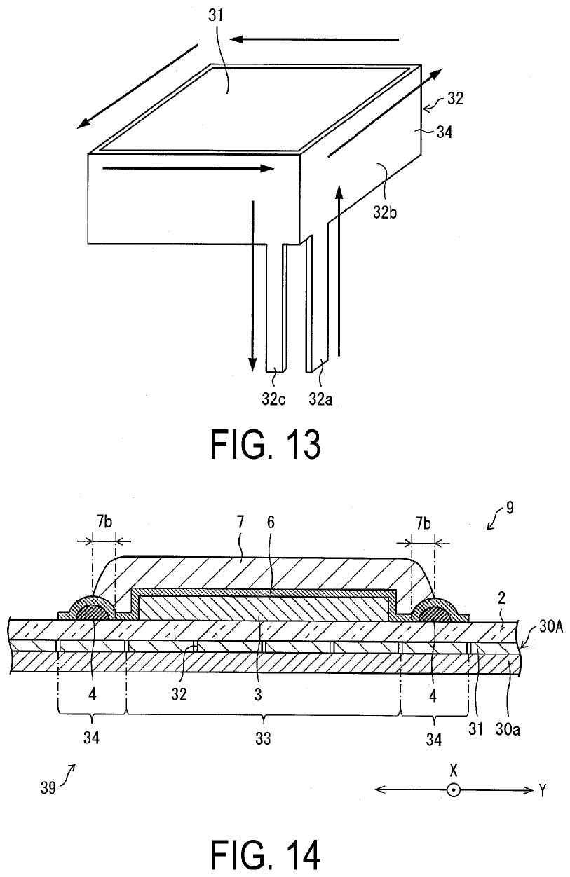

Additionally, the heat insulating portion 32 may have a water cooling type heat insulating mechanism; FIG. 13 is a diagram illustrating an overall configuration of the water cooling type heat insulating portion 32. In FIG. 13, the heat insulating portion 32 includes an inflow pipe 32a, a circulation portion 32b, and a discharge pipe 32c, the circulation portion 32b surrounds the temperature adjustment element 31. The inflow pipe 32a and the discharge pipe 32c are connected to the circulation portion 32b. The temperature adjustment element 31 and the circulation portion 32b make contact with each other. Note that, the temperature adjustment element 31 and the circulation portion 32b may be separated from each other.

As illustrated by arrows in FIG. 13, the water flowing into the circulation portion 32b from the inflow pipe 32a circulates in the circulation portion 32b, travels around the temperature adjustment element 31, and is discharged from the discharge pipe 32c. The heat between the adjacent temperature adjustment elements 31 can be insulated in this manner. In a case where the heat insulating portion 32 is configured with the water cooling type, the configuration may be such that the water can flow in any desired position of the grid shaped heat insulating portion 32. Particularly, by circulating the water in the heat insulating portion 32 between the low temperature portion 34 and the high temperature portion 33, the heat between the low temperature portion 34 and the high temperature portion 33 is insulated. With this, it is possible to maintain the low temperature portion 34 at the first temperature and maintain the high temperature portion 33 at the second temperature with high precision.

As illustrated in FIG. 11 and FIG. 12, in the substrate mounting portion 30A, the low temperature portion 34 is disposed at a position overlapping with the frame-shaped bank 4.

Accordingly, after the ink material 7a is dropped from the nozzle of the ink-jet head 42 and applied on the substrate 1, it is possible to suppress the ink material 7a from flowing in the vicinity of the frame-shaped bank 4. With this, it is possible to suppress the ink from flowing over the frame-shaped bank 4, and as illustrated in FIG. 14, a width of the edge portion 7b, which is a portion having a different film thickness in the organic film 7 formed by the cured ink material 7a, can be narrowed.

As illustrated in FIG. 3, forming the inorganic film 8 on the organic film 7 makes it possible to form the sealing layer 5 in which a width of the edge portion 5a, which is a portion having a different film thickness, is narrow.

As illustrated in FIG. 11 and FIG. 12, in the substrate mounting portion 30A, the high temperature portion 33 is disposed at a position overlapping with the pixel formation region 3. Additionally, the high temperature portion 33 has the second temperature higher than the atmospheric temperature.

Accordingly, heating the portion covering the pixel formation region 3 in the ink material 7a applied on the substrate 1 promotes flowing and promotes leveling of the ink material 7a. With this, the time in relation to the leveling process of the ink material 7a can be shortened. As a result, as illustrated in FIG. 14, the flat organic film 7 can be formed in a short period of time.

Then, as illustrated in FIG. 3, forming the inorganic film 8 on the organic film 7 makes it possible to form the flat sealing layer 5.

### Third Embodiment

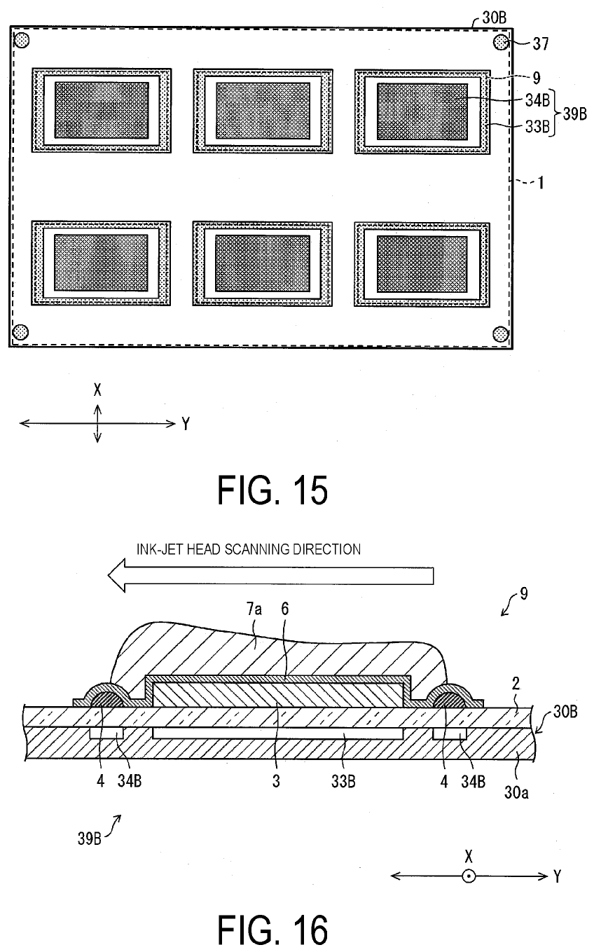

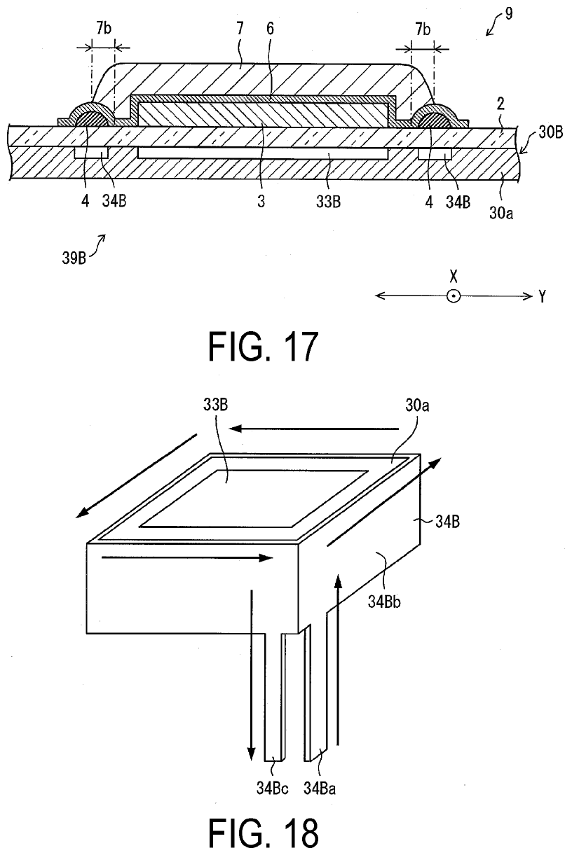

A third embodiment of the disclosure will be described with reference to FIG. 15 to FIG. 18. FIG. 15 is a plan view illustrating a configuration of the substrate mounting portion 30B according to the third embodiment of the disclosure. FIG. 16 is a cross-sectional view in the vicinity of the organic EL display panel formation region of the substrate mounted on the substrate mounting portion 30B. FIG. 17 is a cross-sectional view in the vicinity of the organic EL display panel formation region 9 of the substrate 1 mounted on the substrate mounting portion 30B after the ink material 7a is cured. Note that, in FIG. 16, a direction indicated by an arrow (a direction from right toward left in the diagram) is the scanning direction of the ink-jet head (the application direction of the ink material 7a).

The substrate mounting portion 30B may be provided on at least one of the substrate mounting stage 41 of the ink-jet applying device 13 (FIG. 5) and the substrate mounting stage 21 of the leveling device 14 (FIG. 6).

As illustrated in FIG. 15 and FIG. 16, the substrate mounting portion 30B includes temperature adjustment portions 39B disposed in a matrix shape, each temperature of which being adjusted. The temperature adjustment portion 39B includes a low temperature portion 34B and a high temperature portion 33B, each temperature of which being adjusted.

Between the temperature adjustment portions 39B, a stage base material 30a, which is a metal material configuring the substrate mounting stage 41 or the substrate mounting stage 21, is disposed, and the heat source is not disposed.

The high temperature portion 33B is disposed at a position in a region surrounded by the low temperature portion 34B and corresponding to the pixel formation region 3, and adjusted to the second temperature. The high temperature portion 33B includes a metal plate and a heating mechanism such as a thermoelectric element for heating the metal plate.

In the substrate 1, when the high temperature portion 33B makes contact with the position of the pixel formation region 3, heating a portion covering the pixel formation region 3 in the ink material 7a applied on the substrate 1 promotes flowing of the ink material 7a, and promotes leveling of the ink material 7a. With this, the time in relation to the leveling process of the ink material 7a can be improved.

The low temperature portion 34B is disposed in a frame shape at a position corresponding to the frame-shaped bank 4, and adjusted to the first temperature. The low temperature portion 34B can be configured of air, water, and other heat insulating materials. In a case where the low temperature portion 34B is configured of air, it is sufficient for the low temperature portion 34B to be a groove recessed from a surface of the substrate mounting portion 30B (the mounting surface of the substrate 1).

Additionally, the low temperature portion 34B may have a water cooling type heat insulating mechanism; FIG. 18 is a diagram illustrating an overall configuration of the water cooling type low temperature portion 34B. In FIG. 18, the low temperature portion 34B includes an inflow pipe 34Ba, a circulation portion 34Bb, and a discharge pipe 34Bc, the circulation portion 34Bb surrounds the high temperature portion 33B while being separated from the high temperature portion 33B. The inflow pipe 34Ba and the discharge pipe 34Bc are connected to the circulation portion 34Bb. As illustrated by arrows in FIG. 18, the water flowing into the circulation portion 34Bb from the inflow pipe 34Ba passes through the circulation portion 34Bb, travels around the high temperature portion 33B, and is discharged from the discharge pipe 34Bc. The vicinity of the frame-shaped bank 4 of the substrate 1 can be cooled in this manner.

Accordingly, after the ink material 7a is dropped from the nozzle of the ink-jet head 42 and applied on the substrate 1, it is possible to suppress the ink material 7a from flowing in the vicinity of the frame-shaped bank 4. With this, it is possible to suppress the ink from flowing over the frame-shaped bank 4, and as illustrated in FIG. 17, a width of the edge portion 7b, which is a portion having a different film thickness in the organic film 7 formed by the cured ink material 7a, can be narrowed.

As illustrated in FIG. 3, forming the inorganic film 8 on the organic film 7 makes it possible to form the sealing layer 5 in which a width of the edge portion 5a, which is a portion having a different film thickness, is narrow. With this, a high quality sealing layer 5 can be formed by the ink-jet method. Additionally, the organic EL display device having a frame region with a narrow width in the periphery of the pixel formation region 3 can be formed.

As illustrated in FIG. 15 and FIG. 16, in the substrate mounting portion 30B, the high temperature portion 33B is disposed at a position overlapping with the pixel formation region 3. Additionally, the high temperature portion 33B has the second temperature higher than the atmospheric temperature.

Accordingly, heating the portion covering the pixel formation region 3 in the ink material 7a applied on the substrate 1 promotes flowing and promotes leveling of the ink material 7a. With this, the time in relation to the leveling process of the ink material 7a can be shortened. As a result, as illustrated in FIG. 17, the flat organic film 7 can be formed in a short period of time.

Then, as illustrated in FIG. 3, forming the inorganic film 8 on the organic film 7 makes it possible to form the flat sealing layer 5.

### Fourth Embodiment

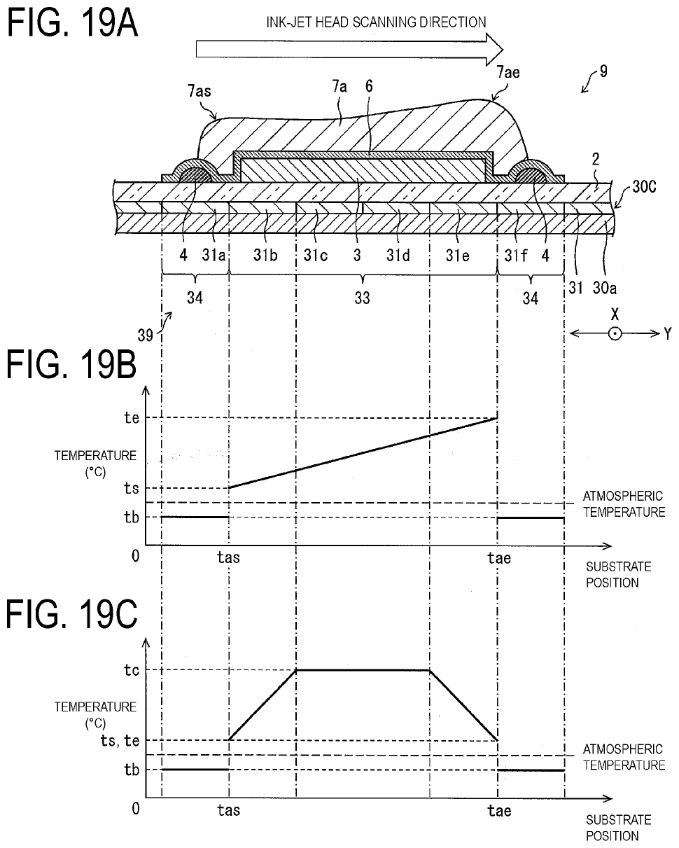

A fourth embodiment of the disclosure will be described with reference to FIGS. 19A to 19C. FIGS. 19A to 19C are diagrams illustrating the substrate mounting portion and a set temperature according to the fourth embodiment of the disclosure. FIG. 19A is a cross-sectional view illustrating a configuration of the substrate mounting portion 30C according to the fourth embodiment of the disclosure, FIG. 19B is a graph illustrating an example of a first temperature gradient of the substrate mounting portion 30C illustrated in FIG. 19A, and FIG. 19C is a graph illustrating an example of a second temperature gradient of the substrate mounting portion 30C illustrated in FIG. 19A.

The substrate mounting portion 30C may be provided on at least one of the substrate mounting stage 41 of the ink-jet applying device 13 (FIG. 5) and the substrate mounting stage 21 of the leveling device 14 (FIG. 6).

The substrate mounting portion 30C is configured such that the high temperature portion 33 has a temperature gradient in the substrate mounting portion 30 (FIG. 8 and FIG. 9). In FIG. 19A, a direction indicated by an arrow (a direction from right toward left in the diagram) is the scanning direction of the ink-jet head (the application direction of the ink material 7a).

As illustrated in FIG. 19A, the ink material 7a applied by the ink-jet applying device 13 (FIG. 5) has different heights at an application start position 7as and an application end position 7ae immediately after the application.

For example, since the residence time at the application start position 7as on the substrate is longer than that at the application end position 7ae, the height of the application start position 7as tends to be low by the leveling effect caused by the residence.

Here, in the cross section of the substrate mounting portion 30C, the temperature adjustment elements 31 configuring the high temperature portion 33 are assumed to include a temperature adjustment element 31b, a temperature adjustment element 31c, a temperature adjustment element 31d, and a temperature adjustment element 31e, from the side closer to the application start position 7as toward the side closer to the application end position 7ae, in this order. Additionally, among the low temperature portions 34 sandwiching the high temperature portion 33, a temperature adjustment element in the vicinity of the temperature adjustment element 31b is assumed to be a temperature adjustment element 31a, and a temperature adjustment element in the vicinity of the temperature adjustment element 31e is assumed to be a temperature adjustment element 31f.

As illustrated in FIGS. 19A and 19B, in the high temperature portion 33, the temperature of each of the temperature adjustment elements 31 is adjusted so as to have a temperature gradient from the temperature adjustment element 31b to the temperature adjustment element 31e (in other words, in the scanning direction of ink-jet head).

This height of the ink material immediately after the application depends on ink material viscosity, setting value for the application of the ink-jet applying device 13, or the like. FIG. 19B illustrates an example in which a temperature gradient is provided such that the temperature in the vicinity of the application start position 7as is higher than that in the vicinity of the application end position 7ae.

As illustrated in FIG. 19A, in a case where the height of the ink material 7a at the application end position 7ae is higher than that at the application start position 7as, as illustrated in FIG. 19B, the temperature of the high temperature portion 33 is adjusted such that a temperature te in the vicinity of the application end position 7ae becomes higher than a temperature ts in the vicinity of the application start position 7as in the high temperature portion 33. This is because it is necessary for the fluidity of the ink material where height is high to be increased in order to level the height of the ink material.

As described above, adjusting the temperature of the high temperature portion 33 to the temperature in accordance with the height of the ink material 7a from the application start position 7as to the application end position 7ae makes it possible to improve leveling speed of the ink material 7a.

Note that, in FIG. 19B as well, the temperatures ts and te of the high temperature portion 33 (the temperature adjustment elements 31b to 31e) opposing the pixel formation region 3 are higher than the atmospheric temperature, the temperature tb of the low temperature portion 34 (the temperature adjustment element 31a and 31f) opposing the frame-shaped bank 4 is the atmospheric temperature or lower.

Additionally, as illustrated in FIG. 19C, in the high temperature portion 33, a central temperature tc may be made relatively high (for example, make the temperatures of the temperature adjustment elements 31c and 31d high), the temperatures ts and te of the edge portions may be made lower than the temperature tc (for example, make the temperatures of the temperature adjustment elements 31b and 31f low).

This makes it possible to flow and level the ink material 7a in the vicinity of the center of the pixel formation region 3. Additionally, the fluidity of the edge portion of the pixel formation region 3 is relatively suppressed in comparison with that in the vicinity of the center and the ink fluidity in the vicinity of the low temperature portion 34 can be suppressed with ease. Accordingly, it is possible to suppress the ink material 7a from flowing over the frame-shaped bank 4 more securely.

Note that, in FIG. 19C as well, the temperatures tc, ts, and to of the high temperature portion 33 (the temperature adjustment elements 31b to 31e) opposing the pixel formation region 3 are higher than the atmospheric temperature, and the temperature tb of the low temperature portion 34 (the temperature adjustment elements 31a and 31f) opposing the frame-shaped bank 4 is the atmospheric temperature or lower.

Furthermore, in the same manner as the organic film 7 illustrated in FIG. 10, the flat organic film 7 in which the edge portion 7b has a narrow width can be formed by the substrate mounting portion 30C illustrated in FIGS. 19A, 19B, and 19C as well. As a result, as illustrated in FIG. 3, the flat sealing layer 5 in which the edge portion 5a has a narrow width can be formed.

Note that, in the same manner in the substrate mounting portions 30A and 30B, the high temperature portions 33A and 33B may have a temperature gradient in accordance with the height from the application start position 7as to the application end position 7ae of the ink material 7a.

### Supplement

A substrate mounting stage according to a first aspect of the disclosure is a substrate mounting stage mounted with organic EL display panel formation regions disposed in a matrix shape, a pixel formation region with pixels disposed in a matrix shape, a frame-shaped bank surrounding the pixel formation region in a frame shape, and an ink material before being cured applied by an ink-jet method configured to cover the pixel formation region in the frame-shaped bank being disposed in the organic EL display panel formation region, the substrate mounting stage includes temperature adjustment portions subjected to a temperature adjustment and disposed in a matrix shape, in which the temperature adjustment portion includes a low temperature portion disposed at a position corresponding to the frame-shaped bank in a frame shape and having a first temperature being an atmospheric temperature or lower.

According to the configuration described above, after the ink material is applied, it is possible to suppress the ink material from flowing in the vicinity of the frame-shaped bank. With this, it is possible to suppress the ink from flowing over the frame-shaped bank, and to narrow a width of an edge portion being a portion with a different film thickness after the ink material is cured. Accordingly, a high quality film can be formed by the ink-jet method. Additionally, the organic EL display device having a frame region with a narrow width in the periphery of the pixel formation region can be formed.

In the substrate mounting stage according to a second aspect of the disclosure, in the first aspect, the temperature adjustment portion may include a high temperature portion disposed at a position corresponding to the pixel formation region in a region surrounded by the low temperature portion and having a second temperature higher than the atmospheric temperature.

According to the configuration described above, fluidity of the ink material covering the pixel formation region is promoted, and leveling of the ink material is promoted. With this, time in relation to a leveling process of the ink material can be improved.

In the substrate mounting stage according to a third aspect of the disclosure, in the second aspect, the substrate mounting stage may include temperature adjustment elements disposed in a matrix shape and having the first temperature, in which the low temperature portion may be configured of a plurality of the temperature adjustment elements.

According to the configuration described above, the low temperature portion can be set in accordance with a shape of the frame-shaped bank. Accordingly, the substrate mounting stage with high versatility can be obtained.

In the substrate mounting stage according to a fourth aspect of the disclosure, in the second aspect, the substrate mounting stage may include temperature adjustment elements disposed in a matrix shape and having the first temperature or the second temperature, in which each of the low temperature portion and the high temperature portion may be configured of a plurality of the temperature adjustment elements.

According to the configuration described above, the low temperature portion and the high temperature portion can be set in accordance with shapes of the frame-shaped bank and the pixel formation region. Accordingly, the substrate mounting stage with high versatility can be obtained.

In the substrate mounting stage according to a fifth aspect of the disclosure, in the third or fourth aspect, a heat insulating portion may be disposed between the low temperature portion and the high temperature portion. According to the configuration described above, it is possible to maintain the low temperature portion at the first temperature and maintain the high temperature portion at the second temperature with high precision.

In the substrate mounting stage according to a sixth aspect of the disclosure, in the fifth aspect, the heat insulating portion may be provided in the periphery of the temperature adjustment element in a grid shape and may include a circulation portion, fluid flowing in the circulation portion.

In the substrate mounting stage according to a seventh aspect of the present disclosure, in the fifth aspect, the heat insulating portion may be provided in the periphery of the temperature adjustment element in a grid shape and may have a groove shape recessed from a surface of the substrate mounting stage.

In the substrate mounting stage according to an eighth aspect of the disclosure, in the second and fourth to seventh aspects, the high temperature portion may be subjected to a temperature adjustment to have a temperature gradient from an application start position to an application end position of the ink material by the ink-jet method.

According to the configuration described above, the high temperature portion can be subjected to the temperature adjustment so as to have a temperature in accordance with a height of the ink material from the application start position to the application end position. With this, the time in relation to the leveling process of the ink material can be improved.

In the substrate mounting stage according to a ninth aspect of the disclosure, in the eighth aspect, the high temperature portion may have a higher temperature in the center of the pixel formation region than in the application start position.

In the substrate mounting stage according to a tenth aspect of the disclosure, in the eighth or ninth aspect, the high temperature portion may have a higher temperature in the center of the pixel formation region than in the application start position and the application end position.

In the substrate mounting stage according to an eleventh aspect of the disclosure, in the third or fourth aspect, the temperature adjustment element may be configured of a Peltier element.

An ink-jet applying device according to a twelfth aspect of the disclosure may include the substrate mounting stage in the first to eleventh aspects and the ink-jet applying device may apply the ink material.

A leveling applying device according to a thirteenth aspect of the disclosure may include the substrate mounting stage in the first to eleventh aspects and the leveling applying device may level the ink material.

A method for manufacturing an organic EL display device according to a fourteenth aspect of the disclosure is a method for manufacturing an organic EL display device to manufacture an organic EL display device from a substrate with organic EL display panel formation regions disposed in a matrix shape,

a pixel formation region with pixels disposed in a matrix shape, a frame-shaped bank surrounding the pixel formation region in a frame shape, and an ink material before being cured applied by an ink-jet method configured to cover the pixel formation region in the frame-shaped bank being disposed in the organic EL display panel formation region,

the method including temperature-adjusting a temperature of a position corresponding to the frame-shaped bank of the substrate to a first temperature being an atmospheric temperature or lower after the ink material is applied by the ink-jet method.

In the method for manufacturing an organic EL display device according to a fifteenth aspect of the disclosure, in the fourteenth aspect 14, in the temperature-adjusting, a temperature of a position corresponding to the pixel formation region of the substrate is preferably further adjusted to the second temperature higher than the atmospheric temperature.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

1 Substrate
2 TFT substrate
3 Pixel formation region
4 Frame-shaped bank
5 Sealing layer
5a Edge portion
6, 8 Inorganic film
7 Organic film
7a Ink material
7ae Application end position
7as Application start position
9 Organic EL display panel formation region
10 Sealing system
11 TFT step S
12 Substrate transport robot
12 Organic EL step S
13 Ink-jet applying device
14 Leveling device
21, 41 Substrate mounting stage
22 UV light source
30, 30A to 30C Substrate mounting portion
31 Temperature adjustment element
32 Heat insulating portion
33, 33A, 33B High temperature portion
34, 34B Low temperature portion
37 Lift pin
39, 39B Temperature adjustment portion
42 Ink-jet head
43 Head support portion

1. A substrate mounting stage mounted with organic EL display panel formation regions disposed in a matrix shape,
a pixel formation region with pixels disposed in a matrix shape, a frame-shaped bank surrounding the pixel formation region in a frame shape, and an ink material before being cured applied by an ink-jet method configured to cover the pixel formation region in the frame-shaped bank being disposed in the organic EL display panel formation region,
the substrate mounting stage comprising:
temperature adjustment portions subjected to a temperature adjustment and disposed in a matrix shape,
wherein the temperature adjustment portion includes a low temperature portion disposed at a position corresponding to the frame-shaped bank in a frame shape and having a first temperature being an atmospheric temperature or lower.

2. The substrate mounting stage according to claim 1,
wherein the temperature adjustment portion includes a high temperature portion disposed at a position corresponding to the pixel formation region in a region surrounded by the low temperature portion and having a second temperature higher than the atmospheric temperature.

3. The substrate mounting stage according to claim 2, further comprising
temperature adjustment elements disposed in a matrix shape and having the first temperature,
wherein the low temperature portion includes a plurality of the temperature adjustment elements.

4. The substrate mounting stage according to claim 2, further comprising
temperature adjustment elements disposed in a matrix shape and having the first temperature or the second temperature,
wherein each of the low temperature portion and the high temperature portion includes a plurality of the temperature adjustment elements.

5. The substrate mounting stage according to claim 3,
wherein a heat insulating portion is disposed between the low temperature portion and the high temperature portion.

6. The substrate mounting stage according to claim 5,
wherein the heat insulating portion is provided in a periphery of the temperature adjustment element in a grid shape and includes a circulation portion that flows fluid in the circulation portion.

7. The substrate mounting stage according to claim 5,
wherein the heat insulating portion is provided in the periphery of the temperature adjustment element in a grid shape and has a groove shape recessed from a surface of the substrate mounting stage.

8. The substrate mounting stage according to claim 2,
wherein the high temperature portion is subjected to a temperature adjustment to have a temperature gradient from an application start position to an application end position of the ink material by the ink-jet method.

9. The substrate mounting stage according to claim 8,
wherein the high temperature portion has a higher temperature level in a center of the pixel formation region than a temperature of the application start position.

10. The substrate mounting stage according to claim 8,
wherein the high temperature portion has a higher temperature level in the center of the pixel formation region than the temperature of the application start position and a temperature of the application end position.

11. The substrate mounting stage according to claim 3,
wherein the temperature adjustment element includes a Peltier element.

12. An ink-jet applying device comprising:
the substrate mounting stage according to claim 1, the ink-jet applying device applying the ink material.

13. A leveling device comprising:
the substrate mounting stage according to claim 1, the leveling device leveling the ink material.

14. A method for manufacturing an organic EL display device to manufacture an organic EL display device from a substrate with organic EL display panel formation regions disposed in a matrix shape,
a pixel formation region with pixels disposed in a matrix shape, a frame-shaped bank surrounding the pixel formation region in a frame shape, and an ink material before being cured applied by an ink-jet method configured to cover the pixel formation region in the frame-shaped bank being disposed in the organic EL display panel formation region,
the method comprising:
temperature-adjusting a temperature of a position corresponding to the frame-shaped bank of the substrate to a first temperature being an atmospheric temperature or lower after the ink material is applied by the ink-jet method.

15. The method for manufacturing an organic EL display device according to claim 14,
wherein in the temperature-adjusting, a temperature of a position corresponding to the pixel formation region of the substrate is further adjusted to the second temperature higher than the atmospheric temperature.
